(19) United States
(12) Patent Application Publication
(10) Pub. No.: US 2015/0380343 A1
(43) Pub. Date: Dec. 31, 2015

(54) FLIP CHIP MMIC HAVING MOUNTING STIFFENER

(71) Applicant: Raytheon Company, Waltham, MA (US)

(72) Inventors: Christopher R. Koontz, Manhattan Beach, CA (US); Jason G. Milne, Hawthorne, CA (US); Tse E. Wong, Los Alamitos, CA (US); Ethan S. Heinrich, San Pedro, CA (US)

(73) Assignee: RAYTHEON COMPANY, Waltham, MA (US)

(21) Appl. No.: 14/317,998

(22) Filed: Jun. 27, 2014

(51) Int. Cl. H01L 23/495; H01L 23/48; H01L 21/48

(52) U.S. Cl. CPC H01L 23/49534; H01L 21/4825; H01L 21/4871; H01L 23/4951; H01L 23/481; H01L 23/49541

(57) ABSTRACT

A flip-chip mounted semiconductor structure having a flip chip mounting pad and a circuit structure flip-chip mounted to the flip chip mounting pad. The circuit structure includes: a semiconductor die; and a stiffener structure attached to the die, the stiffener structure having a conduit passing through the stiffener structure between a front side of the stiffener structure and a hack side of the stiffener structure, the stiffener and attached die having a degree of rigidity greater than the die alone.

### TECHNICAL FIELD

This disclosure relates generally to flip chip MMICs and more particularly to MMICs having relatively thin active semiconductor die.

### BACKGROUND

As is known in the art, Flip chip, also known as controlled collapse chip connection or its acronym, C4, is a method for interconnecting semiconductor devices, such as IC chips and microelectromechanical systems (MEMS), to external circuitry with solder bumps that have been deposited onto the chip pads. The solder bumps are deposited on the chip pads on the top side of the wafer during the final wafer processing step. In order to mount the chip to external circuitry, for example, a circuit board or another chip or wafer, herein sometimes referred to a flip chip mounting pad, the chip is flipped over so that its top side faces down towards the flip chip mounting pad, and aligned so mat its pads align with matching pads on the flip chip mounting pad, and then the solder is re-flowed to complete the interconnect. This is in contrast to wire bonding, in which the chip is mounted upright and wires are used to interconnect the chip pads to external circuitry.

While it is highly desirable to use flip-chip mounting for Monolithic Microwave Integrated Circuit (MMIC) architectures because of their smaller package bonding footprint compared with wire bonding packaging, microstrip power amplifier (PA) MMIC architectures using III-V substrates are not generally flip chip mounted because: (a) the III-V substrate dies are usually 50-100 micron thick and standard supplier processes require chips/wafers to be greater than 100 micron thick for bumping; (b) the thin dies are not mechanically rigid enough for durable chip attachment; and (c) the Radio Frequency (RF) field can extends past the bump height and into the substrate which impacts functional performance.

As is also known in the art, Coplanar Waveguide (CPW) PA circuit architectures (wherein a center conductor is disposed between a pair of ground plane conductors on a front side of the substrate) can be flipped since they have a thickness substrate typically 400-635 micron; however, they cannot use high conductivity thermal interface material because the conductive material causes RF field moding issues. CPWG (Ground) PA circuit architectures (which include a conductor layer on the opposite surface (the backside) of the substrate from the front side CPW PA circuit) attempt to resolve the moding issues of CPW by connecting the conductive layer on the backside of the MMIC to the ground plane conductors forming the CPW on the front side of the substrate using a lithographically formed conductive via passing through the substrates. However, because via depth of the conductive is limited in practice to 100 micron or less, the CPWG wafer cannot exceed 100 micron thickness. This creates the same flip chip mounting issues as microstrip MMICs referred to above.

As is also known in the art, Microstrip, CPW, and CPWG devices are incompatible with some packaging technologies. Existing prior art that attempt to solve these issues essentially falls under three categories:

(a) The first is a removable or permanent passive die stiffener that is employed for the purpose of preventing damage to the wafer during dicing. These appear to be comprised of polymer or plastic materials that would inhibit heat transfer;

(b) The second category of patents, primarily originating from inventor Daoqiang Lu at Intel Corporation, involves attaching a thermally conductive spreader to a die for the purpose of increasing the stiffness of the die and for transferring heat. The attach method is usually by solder, but may be with adhesive. In the patents discovered, the structure always includes the die stiffener as a part of a larger IC package that includes additional thermal interface material and a second package-level spreader. The stiffener is a “metal sheet” and can be attached at the wafer level or chip level; and

(c) The third is in some respects a subset of the second category, but the stiffener is a SiC heat spreader that maybe covalently bonded to the die at the wafer level prior to dicing. This passive heat spreader is only used for heat spreading and must be of greater conductivity than the active die. Additionally, no benefits of reinforcement or stiffening are claimed, and the spreader is a passive device only.

In view of the foregoing, what is needed is a technology that allows flip chip mounting of microstrip and CPWG architectures that is compatible with vendor manufacturing processes for vias and bumping and dicing wafers and minimizes impact to RF performance of the device.

### SUMMARY

In accordance with the present disclosure, a flip-chip mounted semiconductor structure is provided, comprising: (A) a flip chip mounting pad; and (B) a circuit structure flip-chip mounted to the flip chip mounting pad. The circuit structure comprises: (i) a semiconductor die; and (ii) a stiffener structure attached to the die, the stiffener structure having a conduit passing through the stiffener structure between a front side of the stiffener structure and a back side of the stiffener structure, the stiffener and attached die having a degree of rigidity (stiffness) greater than the die alone.

With such an arrangement, the stiffener structure enables a relatively thin semiconductor die to be converted into a sturdier flip-chip mountable circuit structure.

In one embodiment, the semiconductor die has an active semiconductor region formed in a front side of the die and disposed between the flip chip mounting pad and a backside of the semiconductor die.

In one embodiment, a conductive via passes through the die between the front side and a back side of the die.

In one embodiment, a connection is provided comprising: the vertical electrical or thermal conduit and the conductive via.

In one embodiment, the stiffener structure has a cup-shaped cavity formed therein, and wherein the cup-shaped cavity is disposed under the active device region.

In one embodiment, a method is providing for bonding a flip chip mounting pad to circuit structure. The method includes: bonding a stiffener structure to a backside of the die, the stiffener and bonded die having a degree of rigidity greater than the die alone to form the circuit structure; flip chip bonding the circuit structure to the flip chip mounting pad, and forming a conductive conduit through the stiffener structure.

In one embodiment, a conductive via is formed through the semiconductor die.

In one embodiment, a connection is provided comprising the conduit and the conductive via.

With such an arrangement, a passive substrate having a conduit therethrough (e.g., the stiffener structure) is mechanically couple to an active substrate (e.g., the semiconductor substrate) to enable flip-chip mounting of thinned devices (e.g., Microstrip, CPWG MMICs). Also, the arrangement results in improved structural rigidity and thermal performance, electrical/RF interconnects and backside grounding.

Further, the arrangement enables use of highest thermally conductive materials, improving thermal performance; better control of RF fields eliminates moding within band of interest; greater reliability due to better thermal performance; smaller package footprint without wire bonds; and 3D packaging interconnects

The details of one or more embodiments of the disclosure are set forth in the accompanying drawings and the description below. Other features, objects, and advantages of the disclosure will be apparent from the description and drawings, and from the claims.

### DESCRIPTION OF DRAWINGS

FIG. 1 is a simplified cross sectional diagram of a portion of a Radio Frequency (RF) antenna element having a printed circuit wiring board (PWB) serving as a flip chip mounting pad and a circuit structure flip-chip mounted to the flip chip mounting pad 12 according to the disclosure; and

FIG. 2 is a simplified cross sectional diagram of a printed circuit wiring board (PWB) serving as a flip chip mounting pad and a circuit structure flip-chip mounted to the flip chip mounting pad 12 according to the another embodiment of the disclosure.

Like reference symbols in the various drawings indicate like elements.

### DETAILED DESCRIPTION

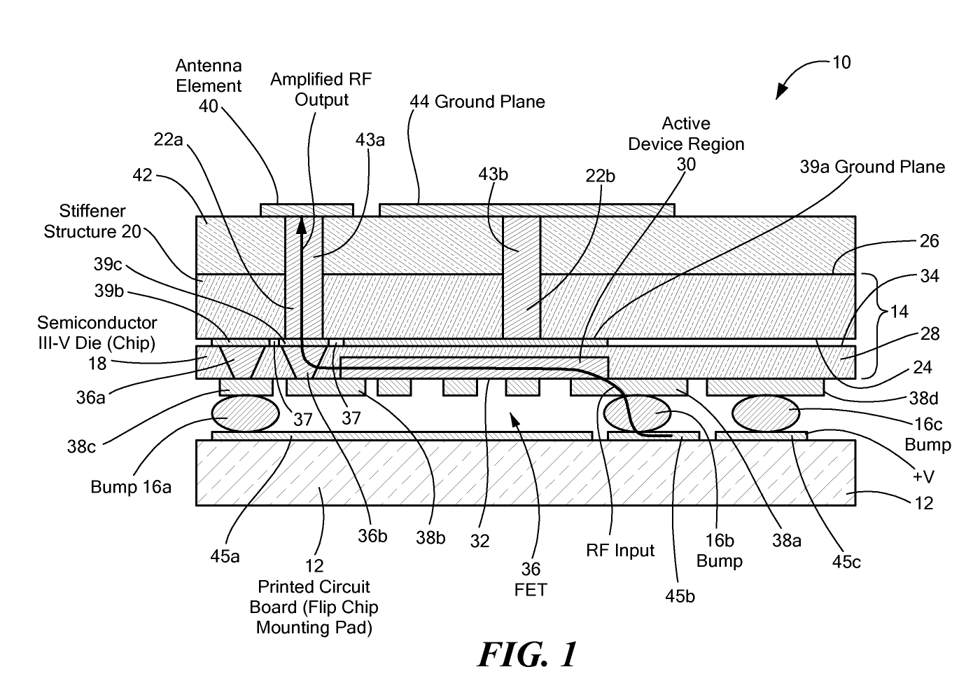

Referring now to FIG. 1, a portion of a Radio Frequency (RF) antenna element 10 is shown. The antenna element 10 includes a printed circuit wiring board (PWB) 12 serving as a flip chip mounting pad; and a circuit structure 14 flip-chip mounted to the flip chip mounting pad 12 through electrically conductive bumps 16. The circuit structure 14 includes: (i) a semiconductor die 18; and (ii) a stiffener structure 20 attached to the die 18, the stiffener structure 20, here, in this example, a dielectric, having conduits 22a, 22b, in this example. The conduits 22a, 22b are here electrical conductors, passing through the stiffener structure 20 between a front side 24 of the stiffener structure 20 and a back side 26 of the stiffener structure 20. The stiffener structure 20 and attached die 18 have a degree of rigidity (stiffness) greater than the die 18 alone. For example, with a 0.15×0.25 inch Si die having a modulus of 2.36×10⁷ psi, then the stiffness is typically 1.15 lb/in for a 100 um thick die and the stiffness for the stiffener when mounted to the chip is typically 73.6 lbs/in.

More particularly, the semiconductor die 18 of the circuit structure 14 is a Monolithic Microwave Integrated Circuit MMIC chip having: a semiconductor substrate 28, here a column III-V semiconductor substrate with an active semiconductor region 30 formed in a front side 32 of the die 18 and disposed between the flip chip mounting pad 12 and a backside 34 of the semiconductor die 18. Here, for example, a Field Effect Transistor (FET) 36 is formed in the active region 30. The front side 32 of the die 18 has thereon contact pads, here contact pads 38a-38d, in this example, connected to the FET 36 using conventional microwave transmission lines, not shown, such as CPW or microstrip transmission lines.

The back side 34 of the die 18 has a ground plane conductor 39a, and in addition, a contact pad 39b, in this example; it being noted that that contact pad 39b is electrically insulated from the ground plane conductor 39a by an opening 37 formed portion of the ground plane conductor 39a. The ground plane conductor 39a has a portion disposed behind the active region 30 and may be used around, plane for the microwave transmission line, not shown.

Conductive vias, here electrical conductors 36a, 36b, in this example, pass through the die 18 between the front side 32 and a back side 34 of the die 18. A connection, here for example, an electrical connection, is provided comprising: the vertical electrical conduit 22a in the stiffener structure 20 and the conductive via 26a through the semiconductor die 18. Here, in this example, the electrical connection couples RF energy on the flip chip mounting pad 12, through a hump 16b, in this example, to an electrical contact 38a on the die 18, here, for example, the gate electrode contact of the FET 36 connected as an RF power amplifier, then after amplification, through the FET 36 to an output electrode pad 38b for example, the drain electrode of the amplifier connected FET 36, then through the conductive via 36b through the die 18, then to the contact 39c, then to the electrical conduit 22a through the stiffener structure 20, to an antenna element 40 of a front end printed circuit board 42, in this example, of the antenna element 10, having a pair of conductors 43a, 43b, in this example, as indicated. It should be understood that the antenna element 40 and ground plane 44 on printed circuit board 42 need not be bonded directly to the stiffener structure 20. The ground plane conductor 39a is connected to a ground plane 44 of the antenna element 40 through the conduit 22b and conductor 43b through the front end of the antenna element 10, as indicated. For example, contact pad 38d may be used to provide a voltage to the FET 36 on the die 18 and contact pad 38c may be used to provide a ground connection between the flip chip mounting pad 12 and the ground plane conductor 39a through bump 16a, contact 38c, via 36a, and conductor 39b which is connected to the ground plane conductor 39a, with conductor 39c being spaced from the ground plane conductor 39a by an opening 37 in the ground plane conductor 39a, as shown. The bumps 16a, 16b and 16c are soldered to printed circuit conductors 45a, 45b and 45c, respectively, of the printed circuit board, (flip chip mounting pad 12) as indicated.

Here, the circuit structure 14 is formed by obtaining a standard III-V wafer, typically having a thickness of greater than 40 microns and forming on the front surface 32 of the die 18, the active region 30, active and passive elements including the FET 36, interconnecting transmission lines, not shown, such as for example, CPW transmission lines and vias 36a, 36b, and contact pads 38a-38d, Next, the back side of the die 18 is thinned using any conventional process so that the thickness of the die 18 is reduced to a range of 50-100 microns. Next, conductors 39a, 39c, and opening 37 are formed using any photo-lithographic process on selected portions of the back side 34 of the thinned die 18.

The stiffener structure 20 is formed as a separate structure. Here, the stiffener structure 20 is, in this example, a dielectric, here for example silicon or silicon carbide or diamond, having a thickness in the range of 50 um to 750 um. The conduits 22a, 22b, in this example, here for example, electrical conductors, are formed through the stiffener structure 20. Having formed both thinned die 18 and the formed stiffener structure are bonded together using any bonding technique, here for example a covalent oxide bond to provide the circuit structure 14. Next, the conductive bumps 16a-16c are formed, as shown, completing the circuit structure 14. Next, the completed circuit structure 14 in flipped upside down and flip chip mounted to the flip chip mounting pad, as shown. As noted above, the stiffener and bonded die having a degree of rigidity greater than the die alone to form the circuit structure. It is noted that the circuit structure 14 may also include additional active and passive circuits, not shown.

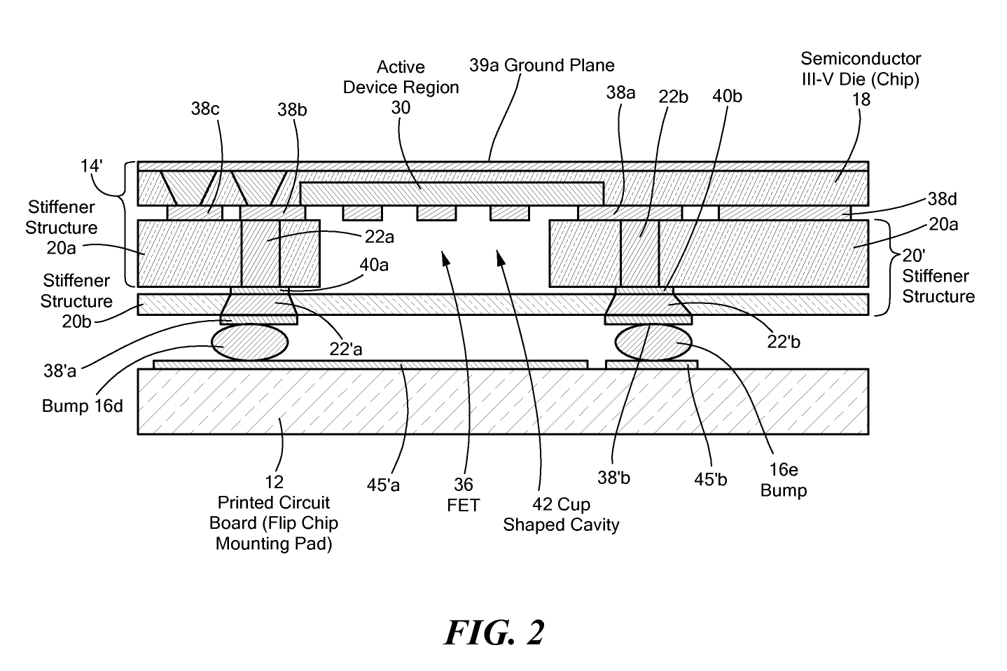

Referring now to FIG. 2, the circuit structure 14′ includes the die 18 and a stiffener structure 20′. Here, the stiffener structure 18′ includes, in this example, two sections 20a, 20b bonded together through conductor pads 40, as shown. It should be understood that other arrangements may be used. For example the structure 14′ may be fabricated as a single section with a cavity.

It is noted that section 20a is formed with an annular opening under the FET 36. The opposing surface of section 20b forms the bottom of a cup-shaped cavity 42 having disposed therein the FET 36, as shown. Section 20a has an electrical conduit 22a passing through it electrically connecting pad 38b to contact 40a and has a conduit 22b passing through it electrically connecting contact 38a to contact 40b, as shown. Section 20b has a conduit passing through it, here a conductive via 22′a electrically connecting contact 40a to contact 38a, as shown, and a conduit passing through it, here via 22′b electrically connecting contact 40b to contact 38′b.

Conductor 45′a of the flip chip mounting pad 12 is electrically connected to contact 38b of the die 18 through, bump 16d, contact 38′a, via 22′a, contact 40a and conduit 22a. Conductor 45′b of the flip chip mounting pad 12 is electrically connected to contact 38a of die 18 through bump 16e, contact 38′b, via 22′b. contact 40b and conduit 22b, as indicated. It should be understood that contacts 40a and 40b may be removed with vias 22′ and 22′b being in direct contact with vias 22a, 22b, respectively.

A number of embodiments of the disclosure have been described. Nevertheless, it will be understood that various modifications may be made without departing from the spirit and scope of the disclosure. For example, the stiffener structures 20, 20′ may have thermally conductive conduits instead or, or in addition, to the electrical conduits described above. In addition the stiffener structure may be formed as a laminated structure. Accordingly, other embodiments are within the scope of the following claims.

What is claimed is:

1. A flip-chip mounted semiconductor structure, comprising:
(A) a flip chip mounting pad;
(B) a circuit structure flip-chip mounted to the Sip chip mounting pad, the circuit structure comprising:
(i) a semiconductor die; and
(ii) a stiffener structure attached to the die, the stiffener structure having a conduit passing through the stiffener structure between a front side of the stiffener structure and a back side of the stiffener structure, the stiffener and attached die having a degree of rigidity greater than the die alone.

2. The flip-chip mounted semiconductor structure recited in claim 1 wherein the semiconductor die has an active semiconductor region formed in a front side of the die and disposed between the flip chip mounting pad and a backside of the semiconductor die.

3. The flip-chip mounted semiconductor structure recited in claim 1 including a conductive via passing through the die between the front side and a back side of the die.

4. The flip-chip mounted semiconductor structure recited in claim 3 wherein a connection is provided comprising: the vertical electrical or thermal conduit and the conductive via.

5. The flip-chip mounted semiconductor structure recited in claim 1 wherein the stiffener structure has a cup-shaped cavity formed therein, and wherein the cup-shaped cavity is disposed under the active device region.

6. A method for bonding a flip chip mounting pad to circuit structure, comprising:
bonding a stiffener structure to a backside of the die, the stiffener and bonded die having a degree of rigidity greater than the die alone to form the circuit structure;
flip chip bonding the circuit structure to the flip chip mounting pad; and
including forming a conductive conduit through the stiffener structure.

7. The method recited in claim 6 including forming a conductive via through the semiconductor die.

8. The method recited in claim 7 including providing a connection comprising: the conduit and the conductive via.
